(19) United States
(12) Patent Application Publication
(10) Pub. No.: US 2019/0131424 A1
(43) Pub. Date: May 2, 2019

(54) METHODS FOR FORMING IC STRUCTURE HAVING RECESSED GATE SPACERS AND RELATED IC STRUCTURES

(71) Applicant: GLOBALFOUNDRIES INC., Grand Cayman (KY)

(72) Inventors: Guowei Xu, Ballston Lake, NY (US); Suraj K. Patil, Ballston Lake, NY (US); Hui Zang, Guilderland, NY (US); Katsunori Onishi, Somers, NY (US); Keith H. Tabakman, Gansevoort, NY (US)

(21) Appl. No.: 15/801,722

(22) Filed: Nov. 2, 2017

(51) Int. Cl. H01L 29/66; H01L 29/417; H01L 29/78

(52) U.S. Cl. CPC H01L 29/6681; H01L 29/7853; H01L 29/41791

(57) ABSTRACT

The present disclosure relates to methods for forming IC structures having recessed gate spacers and related IC structures. A method may include: forming a first and second dummy gate over a fin, each dummy gate having gate spacers disposed on sidewalls thereof such that an opening is disposed between a first gate spacer and a second gate spacer, the opening exposing a source/drain region; recessing the first and second gate spacers; forming an etch stop layer within the opening such that the etch stop layer extends vertically along the recessed first and second gate spacers; forming a dielectric fill over the etch stop layer to substantially fill the opening; replacing the first and second dummy gates with first and second RMG structures; recessing the first and second RMG structures; and forming a gate cap layer over the first and second RMG structures.

### BACKGROUND

### Technical Field

The present disclosure relates to methods for forming integrated circuit structures having recessed gate spacers and related integrated circuit structures.

### Related Art

A typical integrated circuit (IC) chip includes a stack of several levels, or sequentially formed layers, of shapes. Each layer is stacked or overlaid on a prior layer and patterned to form the shapes that define devices (e.g., fin field effect transistors (FinFETs)) or connect the devices into circuits. In a typical state of the art complementary insulated gate FinFET process, such as what is normally referred to as complementary metal-oxide semiconductor (CMOS), layers are formed on a wafer to form the devices on a surface of the wafer. The surface may be the surface of a semiconductor layer on a semiconductor on insulator (SOI) wafer. A simple FinFET includes a gate layer on a semiconductor surface layer. Each of these layers of shapes, also known as mask levels or layers, may be created or printed optically through well-known photolithographic masking, developing and level definition, e.g., etching, implanting, deposition, etc.

Silicon based FinFETs have been successfully fabricated using conventional MOSFET technology. A typical FinFET is fabricated on a substrate with an overlying insulating layer with a thin “fin” extending from the substrate, for example, etched into a silicon layer of the substrate. Irrespective of the physical configuration of the transistor device, each device comprises drain and source regions and a gate structure positioned above and between the source/drain regions. Upon application of an appropriate control voltage to the gate structure, a conductive channel region forms between the drain region and the source region. A double gate may be beneficial in that there is a gate on both sides of the channel allowing gate control of the channel from both sides. Further advantages of FinFETs include reducing the short channel effect and higher current flow. Other FinFET architectures may include three or more effective gates.

As FinFETs continue to shrink in size (e.g., 7 nm and beyond), a shorting between source/drain contacts and gate structures or gate contacts becomes more of a problem due to the relatively small aspect ratio of the opening in which source/drain contacts may be formed. As known in the art, the aspect ratio is representative of the height of a structure divided by its width. In addition, the process window for forming source/drain contacts is quite small and therefore, it may be difficult to form such contacts.

### SUMMARY

A first aspect of the disclosure is directed to method for forming an integrated circuit structure. The method may include: forming a first dummy gate over a fin and forming a second dummy gate over the fin, each dummy gate having gate spacers disposed on sidewalls thereof such that an opening is disposed between a first gate spacer of the first dummy gate and a second gate spacer of the second dummy gate, the opening exposing a source/drain region within the fin; recessing the first gate spacer and the second gate spacer to a height below a height of the first dummy gate and the second dummy gate; forming an etch stop layer within the opening over the exposed source/drain region such that the etch stop layer extends vertically along the recessed first gate spacer and the recessed second gate spacer; forming a dielectric fill over the etch stop layer within the opening and on the etch stop layer to substantially fill the opening; replacing the first dummy gate with a first replacement metal gate (RMG) structure and replacing the second dummy gate with a second RMG structure; recessing the first RMG structure and the second RMG structure; and forming a gate cap layer over each of the first RMG structure and the second RMG structure.

A second aspect of the disclosure is directed to an integrated circuit structure. The integrated circuit structure may include: a fin including a source/drain region therein; a first replacement metal gate (RMG) structure and a second RMG structure over the fin on opposing sides of the source/drain region, each RMG structure having a pair of gate spacers disposed on opposing sidewalls thereof; a first gate spacer of the pair of gate spacers of the first RMG structure having a height that is greater than a height of the first RMG structure; a second gate spacer of the pair of gate spacers of the second RMG structure having a height that is greater than a height of the second RMG structure; and an etch stop layer over the source/drain region within the fin and extending vertically along sidewalls of and over a top surface of each of the first gate spacer and the second gate spacer.

A third aspect of the disclosure is directed to method for forming an integrated circuit structure. The method may include: forming a first dummy gate over a fin and forming a second dummy gate over the fin, each dummy gate having gate spacers disposed on sidewalls thereof such that an opening is disposed between a first gate spacer of the first dummy gate and a second gate spacer of the second dummy gate, the opening exposing a source/drain region within the fin; recessing the first gate spacer and the second gate spacer to a height below a height of the first dummy gate and the second dummy gate; forming an etch stop layer within the opening over the exposed source/drain region such that the etch stop layer extends vertically along the recessed first gate spacer and the recessed second gate spacer; forming a dielectric fill over the etch stop layer within the opening to substantially fill the opening; replacing the first dummy gate with a first replacement metal gate (RMG) structure and replacing the second dummy gate with a second RMG structure; recessing the first RMG structure and the second RMG structure, wherein the recessing of the first RMG structure and the second RMG structure includes recessing the first RMG structure and the second RMG structure to a height below the height of the first gate spacer and the second gate spacer; forming a gate cap layer over each of the first RMG structure and the second RMG structure; removing the dielectric fill to expose the etch stop layer thereunder; and forming a source/drain contact over the etch stop layer.

The foregoing and other features of the disclosure will be apparent from the following more particular description of embodiments of the disclosure.

### BRIEF DESCRIPTION OF THE DRAWINGS

The embodiments of this disclosure will be described in detail, with reference to the following figures, wherein like designations denote like elements, and wherein:

FIG. 1 shows a top-down view of an integrated circuit structure according to embodiments of the disclosure.

FIG. 2 shows a cross-sectional view of the integrated circuit structure taken along line A-A of FIG. 1.

FIGS. 3-10 show cross-sectional views of the integrated circuit structure taken along line B-B of FIG. 1 as it undergoes aspects of a method according to embodiments of the disclosure.

It is noted that the drawings of the disclosure are not to scale. The drawings are intended to depict only typical aspects of the disclosure, and therefore should not be considered as limiting the scope of the disclosure. In the drawings, like numbering represents like elements between the drawings.

### DETAILED DESCRIPTION

The present disclosure relates to methods for forming integrated circuit structures having recessed gate spacers and related integrated circuit structures. The present disclosure provides for methods and structures having recessed gate spacers and replacement metal gate structures such that a height of the recessed gate spacers are greater than a height of the replacement metal gate structures. More specifically, the methods described herein include recessing gate spacers disposed between adjacent dummy gates to increase a width of an opening disposed over a source/drain region between the adjacent dummy gates. By increasing a width of the opening, the aspect ratio (aspect ratio=height of the opening/width of the opening) of the opening is increased. In this way, the process window for forming a source/drain contact therein is improved. In addition, after the width of the opening is increased, the dummy gates are replaced with replacement metal gate (RMG) structures, and the RMG structures are recessed to a height below a height of the recessed gate spacers. As a result, less shorting occurs between the RMG structures and later formed source/drain contacts.

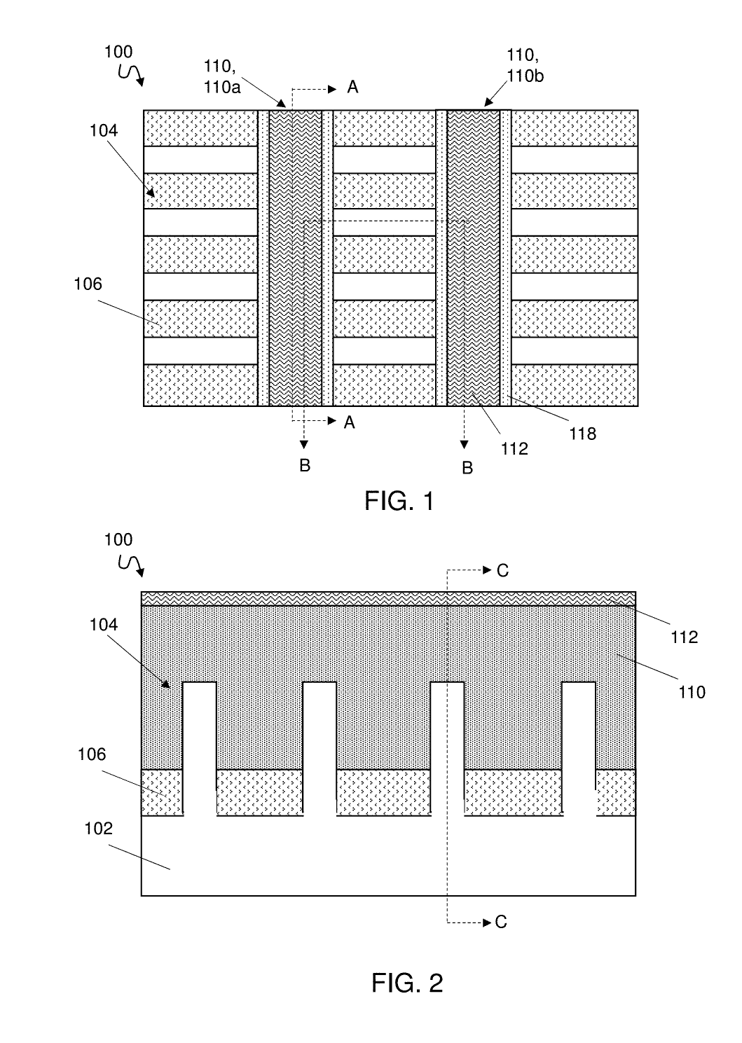

FIG. 1 shows a top-down view of a preliminary integrated circuit (IC) structure 100 according to embodiments of the disclosure. FIG. 2 shows a cross-sectional view of IC structure 100 taken along line A-A of FIG. 1. Referring to FIGS. 1 and 2 together, IC structure 100 may include a substrate 102 (FIG. 2). Substrate 102 may include any currently-known or later developed material capable of being processed into a transistor structure, and may include, e.g., a bulk semiconductor layer, a semiconductor-on-insulator (SOI) substrate, etc. Substrate 102 thus may overlie one or more other layers of material having distinct material and/or electrical properties, with such layers of material being omitted from the accompanying FIGS. to better illustrate structures and processes to form an IC structure according to the disclosure. Substrate 102 may include any currently known or later developed semiconductor material, which may include without limitation, silicon, germanium, silicon carbide, and those consisting essentially of one or more III-V compound semiconductors having a composition defined by the formula Al_{X1}Ga_{X2}In_{X3}As_{Y1}P_{Y2}N_{Y3}Sb_{Y4}, where X1, X2, X3, Y1, Y2, Y3, and Y4 represent relative proportions, each greater than or equal to zero and X1+X2+X3+Y1+Y2+Y3+Y4=1 (1 being the total relative mole quantity). Other suitable substrates include II-VI compound semiconductors having a composition Zn_{A1}Cd_{A2}Se_{B1}Te_{B2}, where A1, A2, B1, and B2 are relative proportions each greater than or equal to zero and A1+A2+B1+B2=1 (1 being a total mole quantity). Furthermore, the entirety of substrate 102 or a portion thereof may be strained. Substrate 102 of IC structure 100 may be formed by forming a semiconductor material on an underlying structure (not shown). According to an example, substrate 102 can be formed by deposition and/or wafer bonding, e.g., separation by implantation of oxygen (SIMOX).

IC structure 100 may also include a set of fins 104 and an isolation region 106, e.g., shallow trench isolation (STI), disposed between adjacent fins and over substrate 102. Isolation region 106 may include any suitable isolation material, e.g., silicon oxide. Isolation region 106 may be formed by any suitable process including etching a trench (not shown) within substrate 102, and filling, e.g., by depositing, the trench with the isolation material. Set of fins 104 may be formed from substrate 102 by any suitable process including one or more photolithography and etch processes. While four fins are shown, it is to be understood that any number of fins may be employed without departing from aspects of the disclosure.

As used herein, the term “depositing” may include any now known or later developed technique appropriate for deposition, including but not limited to, for example: chemical vapor deposition (CVD), low-pressure CVD (LPCVD), plasma-enhanced CVD (PECVD), semi-atmosphere CVD (SACVD) high density plasma CVD (HDPCVD), rapid thermal CVD (RTCVD), ultra-high vacuum CVD (UHVCVD), limited reaction processing CVD (LRPCVD), metalorganic CVD (MOCVD), sputtering deposition, ion beam deposition, electron beam deposition, laser assisted deposition, thermal oxidation, thermal nitridation, spin-on methods, physical vapor deposition (PVD), atomic layer deposition (ALD), chemical oxidation, molecular beam epitaxy (MBE), plating, and evaporation.

As used herein, “etching” generally refers to the removal of material from a substrate or structures formed on the substrate by wet or dry chemical means. In some instances, it may be desirable to selectively remove material from certain areas of the substrate. In such an instance, a mask may be used to prevent the removal of material from certain areas of the substrate. There are generally two categories of etching, (i) wet etch and (ii) dry etch. Wet etching may be used to selectively dissolve a given material and leave another material relatively intact. Wet etching is typically performed with a solvent, such as an acid. Dry etching may be performed using a plasma which may produce energetic free radicals, or species neutrally charged, that react or impinge at the surface of the wafer. Neutral particles may attack the wafer from all angles, and thus, this process is isotropic. Ion milling, or sputter etching, bombards the wafer with energetic ions of noble gases from a single direction, and thus, this process is highly anisotropic. A reactive-ion etch (RIE) operates under conditions intermediate between sputter etching and plasma etching and may be used to produce deep, narrow features, such as trenches.

Still referring to FIGS. 1 and 2, one or more dummy gates 110 may be formed over and extending perpendicular to set of fins 104. Dummy gates 110 may include any suitable dummy gate material such as, for example, polysilicon. Overlying dummy gate 110 may be a cap layer 112, e.g., silicon nitride. Further, gate spacers 118 may be formed on opposing sidewalls of dummy gates 110. Gate spacers 118 may include, for example, a dielectric layer having a low dielectric constant (e.g., less than 3.9). Such materials may include, e.g., silicon oxide (SiO₂), silicon oxygen carbon nitride (SiOCN), silicon carbon boron nitride (SiBCN). Dummy gates 110, cap layer 112, and gate spacers 118 may be formed by conventional deposition and etching techniques. As shown in FIG. 1, a first dummy gate 110a and a second dummy gate 110b may be formed over and extending perpendicular to set of fins 104. While two dummy gates are shown, it is to be understood that any number of dummy gates can be employed without departing from aspects of the disclosure.

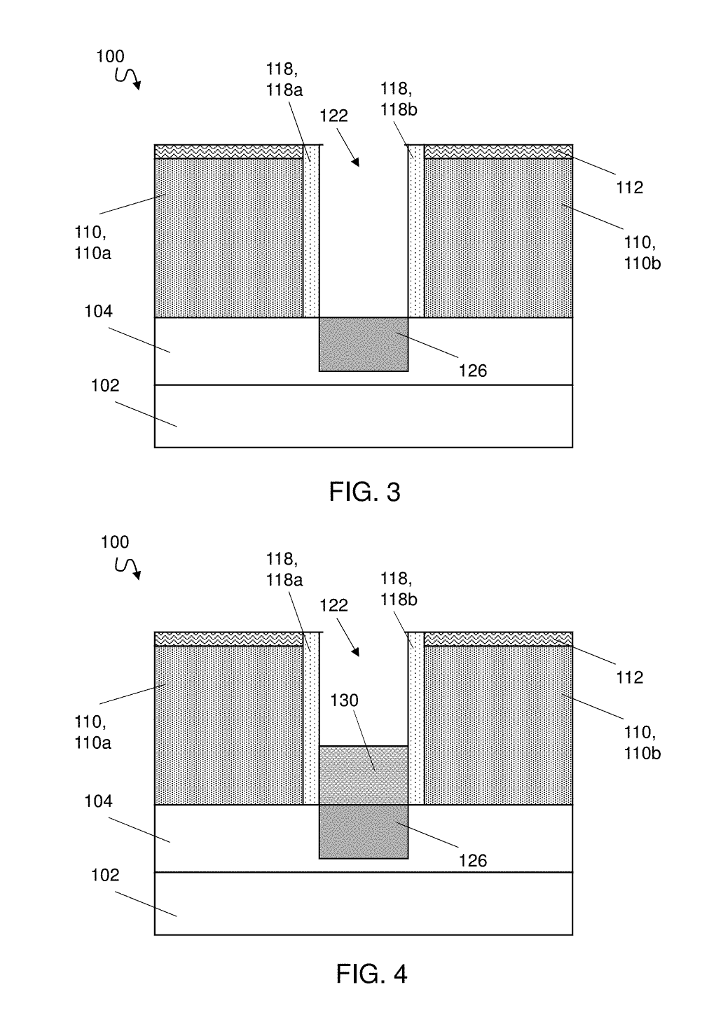

FIG. 3 shows a cross-sectional taken along line B-B of FIG. 1 and line C-C of FIG. 2. As shown in FIG. 3, dummy gates 110 may be formed such that there is an opening 122 defined between a first gate spacer 118a of first dummy gate 110a and a second gate spacer 118b of second dummy gate 110b. Within opening 122, a source/drain region 126 may be formed and exposed within and/or over fins 104. Source/drain region 126 may be formed, e.g., by epitaxial growth of a semiconductor material over fin 104 or by doping of fin 104 via ion implantation of n-type or p-type dopants (not shown). N-type is element introduced to semiconductor to generate free electron (by “donating” electron to semiconductor) and must have one more valance electron than semiconductor. Common donors in silicon (Si): phosphorous (P), arsenic (As), antimony (Sb) and in gallium arsenic (GaAs): sulphur (S), selenium (Se), tin (Sn), silicon (Si), and carbon (C). P-type is element introduced to semiconductor to generate free hole (by “accepting” electron from semiconductor atom and “releasing” hole at the same time) and the acceptor atom must have one valence electron less than host semiconductor. Boron (B) is the most common acceptor in silicon technology. However, alternatives include indium (In) and gallium (Ga).

The terms “epitaxial growth and/or deposition” and “epitaxially formed and/or grown” mean the growth of a semiconductor material on a deposition surface of a semiconductor material, in which the semiconductor material being grown may have the same crystalline characteristics as the semiconductor material of the deposition surface. In an epitaxial deposition process, the chemical reactants provided by the source gases are controlled and the system parameters are set so that the depositing atoms arrive at the deposition surface of the semiconductor substrate with sufficient energy to move around on the surface and orient themselves to the crystal arrangement of the atoms of the deposition surface. Therefore, an epitaxial semiconductor material may have the same crystalline characteristics as the deposition surface on which it may be formed. For example, an epitaxial semiconductor material deposited on a {100} crystal surface may take on a {100} orientation. In some embodiments, epitaxial growth and/or deposition processes may be selective to forming on semiconductor surfaces, and may not deposit material on dielectric surfaces, such as silicon dioxide or silicon nitride surfaces.

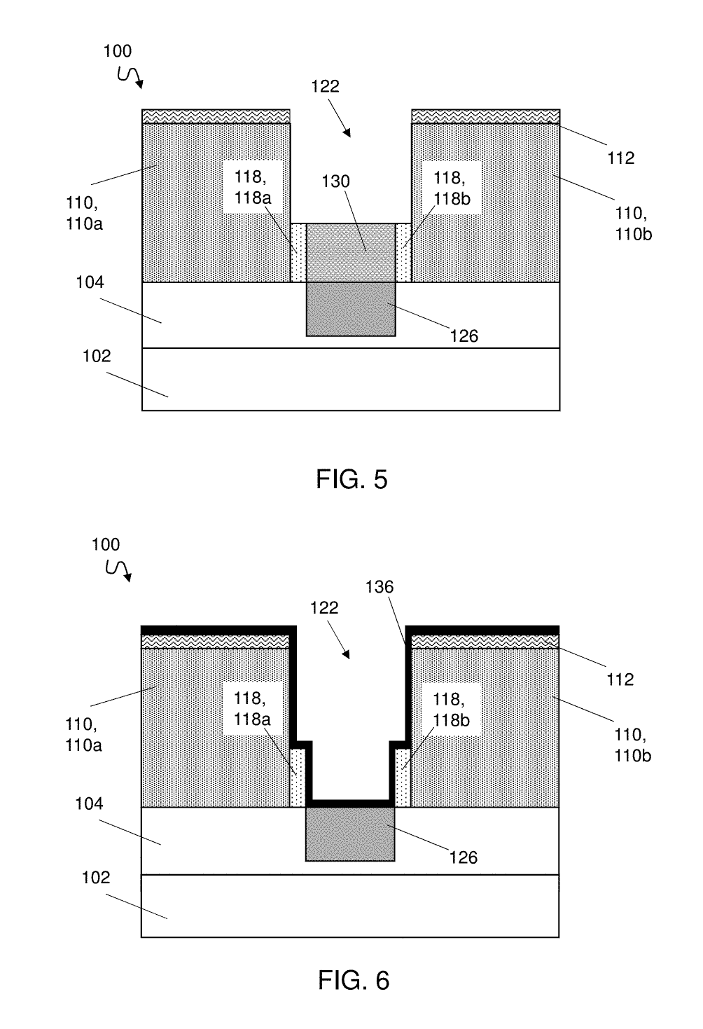

Turning now to FIG. 4, a mask 130 may be formed over IC structure 100 and etched, e.g., via RIE, such that mask 130 remains only within opening 122 over source/drain region 126. Additionally, mask 130 may be etched to a height below a height of dummy gates 110. Mask 130 may include, e.g., an organic polymerization layer (OPL). With mask 130 in place, first gate spacer 118a and second gate spacer 118b may be recessed to approximately the height of mask 130 as shown in FIG. 5. That is, first gate spacer 118a and second gate spacer 118b may be recessed such that first gate spacer 118a and second gate spacer 118b are recessed to a height below the height of dummy gates 110. First gate spacer 118a and second gate spacer 118b may be recessed to a height slightly higher than or equal to a final metal gate height, as will be described further herein. This recessing may include performing an isotropic RIE of first gate spacer 118a and second gate spacer 118b such that a portion of gate spacers 118a, 118b positioned above the height of mask 130 is removed. The recessing of first and second gate spacers 118a, 118b may expose portions of sidewalls of dummy gates 110. Subsequently, as shown in FIG. 6, mask 130 may be removed, e.g., via etching or ashing away, from opening 122 to expose source/drain region 126 thereunder.

As also shown in FIG. 6, an etch stop layer 136 may be formed within opening 122 over exposed source/drain region 126. More specifically, etch stop layer 136 may be conformally deposited over IC structure 100. Etch stop layer 136 may extend vertically along sidewalls of recessed first gate spacer 118a and second gate spacers 118b. In addition, etch stop layer 136 may be formed over a top surface of first gate spacer 118a and second gate spacer 118b such that etch stop layer 136 extends vertically along exposed portions of sidewalls of dummy gates 110. Further, as shown in FIG. 6, etch stop layer 136 may be formed over a top surface of cap layer 112. Etch stop layer 136 may include, e.g., silicon nitride (SiN).

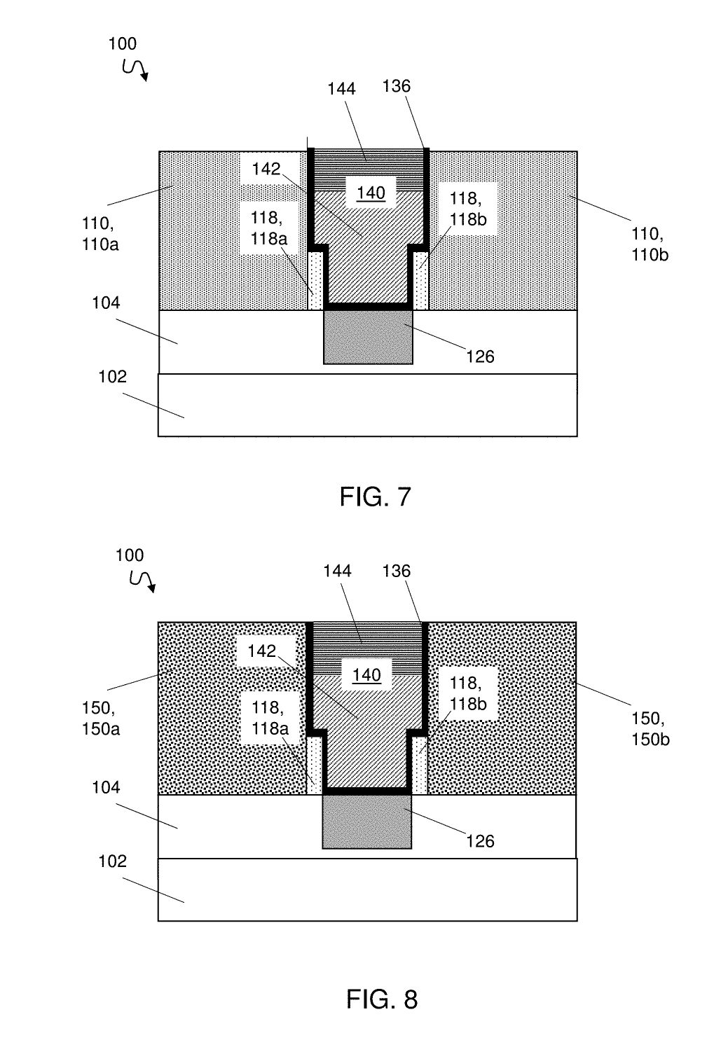

Turning now to FIG. 7, etch stop layer 136 and cap layer 112 (FIG. 6) may be removed, e.g., via etching, from a top surface of dummy gates 110 to expose first and second dummy gates 110a, 110b. Further, a dielectric fill 140 may be formed over etch stop layer 136 within opening 122 (FIG. 6) and on etch stop layer 136 to substantially fill opening 122. Dielectric fill 140 may be formed by, e.g., forming a first oxide 142 (e.g., via deposition) over etch stop layer 136 within opening 122 to substantially fill opening 122. Subsequently, first oxide 142 may be recessed, e.g., via etching, to a height above a height of first gate spacer 118a and second gate spacer 118b. Recessing of first oxide 142 may expose etch stop layer 136 extending vertically along sidewalls of dummy gates 110. A second oxide 144 may then be formed, e.g., via deposition, over first oxide 142 and planarized to a top surface of etch stop layer 136 disposed over cap layer 112. Planarization refers to various processes that make a surface more planar (that is, more flat and/or smooth). Chemical-mechanical-polishing (CMP) is one currently conventional planarization process which planarizes surfaces with a combination of chemical reactions and mechanical forces. First oxide 142 may include, e.g., Tonen SilaZene (TSOZ) oxide, and second oxide 144 may include, e.g., an oxide formed by a high-density plasma (HDP) CVD. As shown in FIG. 7, dielectric fill 140 may be substantially T-shaped. More specifically, first oxide 142 may be substantially T-shaped within opening 122. That is, first oxide 142 may be substantially T-shaped such that a portion of first oxide 142 is disposed over portions of etch stop layer 136 that are disposed over a top surface of each of first gate spacer 118a and second gate spacer 118b.

Turning now to FIG. 8, the method may include replacing dummy gates 110 with replacement metal gate (RMG) structures 150. More specifically, first dummy gate 110a may be replaced with a first RMG structure 150a and second dummy gate 110b may be replaced with a second RMG structure 150b. Dummy gates 110 may be removed, e.g., via etching, and RMG structures 150 may be formed, e.g., by deposition of any now known or later developed gate material and planarization. For example, RMG structures 150 may include a work function metal and/or a gate conductor. As known in the art, work function metal layers may act as a doping source, and a different work function setting metal can then be employed depending on whether a n-type field-effect-transistor (NFET) or a p-type field-effect-transistor (PFET) device is desired. Thus, the same gate conductor can be used in each of the devices, yet a different (if so desired) work function setting metal can be used in one or more devices to obtain a different doping polarity. By way of example only, suitable work function setting metals for use in PFET devices include, but are not limited to aluminum, dysprosium, gadolinium, and ytterbium. Suitable work function setting metals for use in NFET devices include, but are not limited to lanthanum, titanium, and tantalum. Optional barrier layers may also be provided and include, for example, titanium nitride, tantalum nitride, hafnium nitride, hafnium silicon nitride, titanium silicon nitride, tantalum silicon nitride, tungsten nitrogen carbide, and hafnium aluminum nitride. Gate conductor layers may include, for example, at least one of: titanium, titanium nitride, tungsten, tungsten nitride, copper, copper nitride, tantalum, or tantalum nitride.

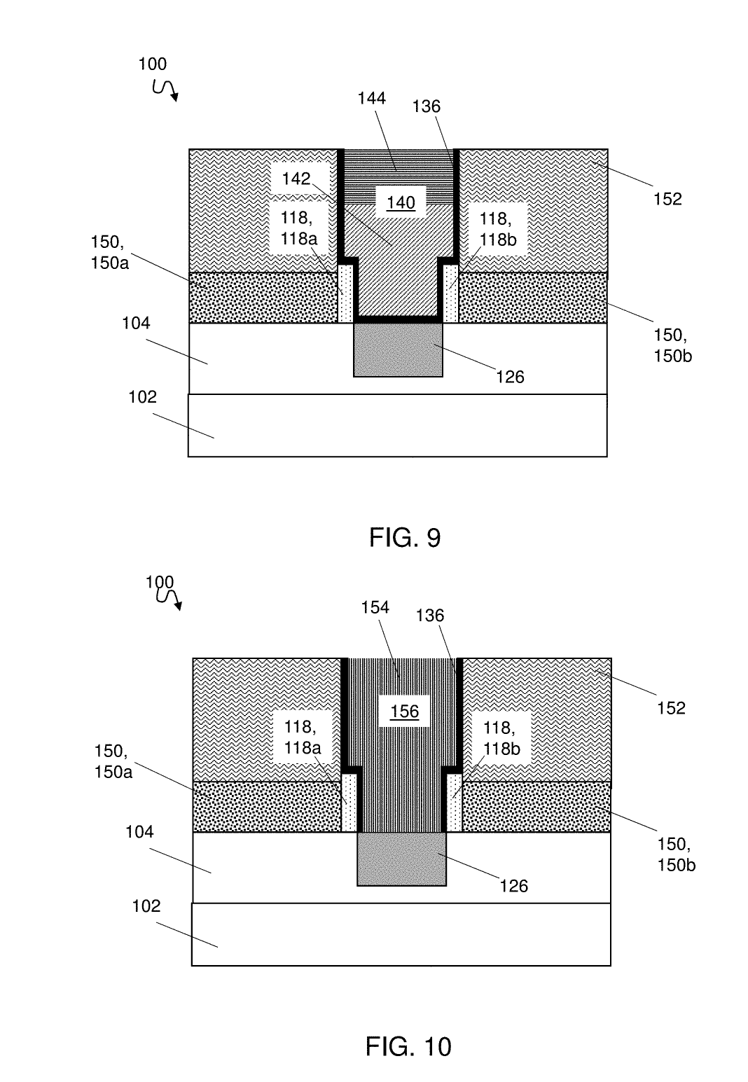

As shown in FIG. 9, the method may include recessing, e.g., via etching, RMG structures 150 to a height below the height of gate spacers 118. More specifically, first RMG structure 150a may be recessed to a height below the height of first gate spacer 118a. Additionally, second RMG structure 150b may be recessed to a height below the height of second gate spacer 118b. The recessing of RMG structures 150 may include recessing RMG structures 150 to a height below a height of first oxide 142. Further, a gate cap layer 152 may be formed, e.g., via deposition, over recessed RMG structures 150 and planarized to a top surface of etch stop layer 136 and dielectric fill 140. Gate cap layer 152 may include any now known or later developed gate cap material, e.g., silicon nitride.

At this point, IC structure 100 may include fin 104 having source/drain region 126 therein. First RMG structure 150a and second RMG structure 150b may be disposed over fin 104 on opposing sides of source/drain region 126. Each RMG structure 150 may include a pair of gate spacers 118 disposed on opposing sidewalls thereof. First gate spacer 118a of first RMG structure 150a may have a height that is greater than a height of first RMG structure 150a. Second gate spacer 118b of second RMG structure 150b may have a height that is greater than a height of second RMG 150b. Etch stop layer 136 may be disposed over source/drain region 126 and extend vertically along sidewalls of and over a top surface of each of first gate spacer 118a and second gate spacer 118b. Further, IC structure 100 may include gate cap layer 152 over each of first and second RMG structures 150a, 150b. Etch stop layer 136 may extend vertically along a sidewall of gate cap layer 152 as shown in FIG. 9. In addition, dielectric fill 140, including first oxide 142 and second oxide 144, may be disposed over etch stop layer and between first and second RMG structures 150. Dielectric fill 140 (or more specifically, first oxide 142 of dielectric fill 140) may be substantially T-shaped such that a portion of dielectric fill 140 is disposed over a top surface of each of first and second gate spacers 118a, 118b.

Turning now to FIG. 10, dielectric fill 140 may be removed via etching to expose etch stop layer 136 thereunder. Subsequently, a portion of etch stop layer 136 may be removed from opening 122 (FIG. 6) to expose source/drain region 126 thereunder. However, portions of etch stop layer 136 may remain extending vertically along gate spacers 118 and gate cap layer 152. That is, portions of etch stop layer 136 that are disposed directly over or in contact with source/drain region 126 may be removed. Further, a metal 154 may be formed, e.g., via deposition, over source/drain region 126 and in contact with source/drain region 126 to define a source/drain contact 156. In some embodiments, source/drain contact 156 may include multiple layers, such as one or more barrier layers (e.g., Ta, TaN, TiN, etc.) to prevent migration of any metal (e.g., copper) surrounding structures, a metal seed layer (e.g., copper), a metal fill material (e.g., copper), a metal silicide material, etc., although such additional layers are not separately depicted in the drawings. Source/drain contact 156 may be substantially T-shaped such that a portion of source/drain contact 156 is disposed over a top surface of each of first and second gate spacers 118a, 118b. At this point, IC structure 100 may include fin 104 having source/drain region 126 therein. First RMG structure 150a and second RMG structure 150b may be disposed over fin 104 on opposing sides of source/drain region 126. Each RMG structure 150 may include a pair of gate spacers 118 disposed on opposing sidewalls thereof. First gate spacer 118a of first RMG structure 150a may have a height that is greater than a height of first RMG structure 150a. Second gate spacer 118b of second RMG structure 150b may have a height that is greater than a height of second RMG 150b. Etch stop layer 136 may be disposed over source/drain region 126 and extend vertically along sidewalls of and over a top surface of each of first gate spacer 118a and second gate spacer 118b. Further, IC structure 100 may include gate cap layer 152 over each of first and second RMG structures 150a, 150b. Etch stop layer 136 may extend vertically along a sidewall of gate cap layer 152 as shown in FIG. 10. However, source/drain contact 156 may be disposed over source/drain region 126 and between RMG structures 150, extending through etch stop layer 136. As shown, source/drain contact 156 may be substantially T-shaped such that a portion of source/drain contact 156 is disposed over a top surface of each of first and second gate spacers 118a, 118b.

The present disclosure provides for methods and structures having recessed gate spacers and replacement metal gate structures such that a height of the recessed gate spacers are greater than a height of the replacement metal gate structures. More specifically, the methods described herein include recessing gate spacers disposed between adjacent dummy gates to increase a width of an opening disposed over a source/drain region between the adjacent dummy gates. By increasing a width of the opening, the aspect ratio (aspect ratio =height of the opening/width of the opening) of the opening is increased. In this way, the process window for forming a source/drain contact therein is improved. In addition, after the width of the opening is increased, the dummy gates are replaced with replacement metal gate (RMG) structures, and the RMG structures are recessed to a height below a height of the recessed gate spacers. As a result, less shorting occurs between the RMG structures and later formed source/drain contacts.

The method(s) as described above is used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The terminology used herein is for the purpose of describing particular embodiments only and is not intended to be limiting of the disclosure. As used herein, the terms “first,” “second,” and the like, do not denote any order, quantity, or importance, but rather are used to distinguish one element from another. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. “Optional” or “optionally” means that the subsequently described event or circumstance may or may not occur, and that the description includes instances where the event occurs and instances where it does not.

Approximating language, as used herein throughout the specification and claims, may be applied to modify any quantitative representation that could permissibly vary without resulting in a change in the basic function to which it is related. Accordingly, a value modified by a term or terms, such as “about,” “approximately” and “substantially,” are not to be limited to the precise value specified. In at least some instances, the approximating language may correspond to the precision of an instrument for measuring the value. Here and throughout the specification and claims, range limitations may be combined and/or interchanged, such ranges are identified and include all the sub-ranges contained therein unless context or language indicates otherwise. “Approximately” as applied to a particular value of a range applies to both values, and unless otherwise dependent on the precision of the instrument measuring the value, may indicate +/−10% of the stated value(s). “Substantially” refers to largely, for the most part, entirely specified or any slight deviation which provides the same technical benefits of the disclosure.

The corresponding structures, materials, acts, and equivalents of all means or step plus function elements in the claims below are intended to include any structure, material, or act for performing the function in combination with other claimed elements as specifically claimed. The description of the present disclosure has been presented for purposes of illustration and description, but is not intended to be exhaustive or limited to the disclosure in the form disclosed. Many modifications and variations will be apparent to those of ordinary skill in the art without departing from the scope and spirit of the disclosure. The embodiment was chosen and described in order to best explain the principles of the disclosure and the practical application, and to enable others of ordinary skill in the art to understand the disclosure for various embodiments with various modifications as are suited to the particular use contemplated.

1. A method for forming an integrated circuit structure, the method comprising:
forming a first dummy gate over a fin and forming a second dummy gate over the fin, each dummy gate having gate spacers disposed on sidewalls thereof such that an opening is disposed between a first gate spacer of the first dummy gate and a second gate spacer of the second dummy gate, the opening exposing a source/drain region within the fin;
recessing a height of the first gate spacer and the second gate spacer to a reduced height below a height of the first dummy gate and the second dummy gate;
forming an etch stop layer within the opening over the exposed source/drain region such that the etch stop layer extends vertically along the recessed first gate spacer and the recessed second gate spacer;
forming a dielectric fill over the etch stop layer within the opening and on the etch stop layer to substantially fill the opening;
replacing the first dummy gate with a first replacement metal gate (RMG) structure and replacing the second dummy gate with a second RMG structure;
recessing the first RMG structure and the second RMG structure;
forming a gate cap layer over each of the first RMG structure and the second RMG structure;
removing the dielectric fill and the etch stop layer to form a contact opening over the fin, the contact opening including a lower portion horizontally between the recessed first gate spacer and the recessed second gate spacer, and an upper portion horizontally between the first RMG structure and the second RMG structure; and
filling the contact opening with a contact metal, the contact metal extending continuously from an upper surface of the fin to a height substantially coplanar with the first RMG structure and the second RMG structure, wherein a lower portion of the contact metal horizontally between the recessed first gate spacer and the recessed second gate spacer includes a first width, and an upper portion of the contact metal horizontally between the first RMG structure and the second RMG structure has a second width greater than the first width.

2. The method of claim 1, wherein the recessing of the first RMG structure and the second RMG structure includes recessing the first RMG structure and the second RMG structure to a height below the reduced height of the first gate spacer and the second gate spacer.

3. The method of claim 1, wherein the forming of the dielectric fill includes:
forming a first oxide over the etch stop layer to substantially fill the opening;
recessing the first oxide to a height above the reduced height of the first and second gate spacers;
forming a second oxide over the first oxide; and
planarizing the second oxide to the first and second RMG structure.

4. The method of claim 3, wherein the first oxide is substantially T-shaped after the recessing of the first oxide.

5. The method of claim 3, wherein the forming of the second oxide includes high-density plasma chemical vapor deposition of the second oxide.

6. The method of claim 3, wherein the recessing of the first and second RMG structures includes recessing the first and second RMG structures to a height below the height of the first oxide.

7. (canceled)

8. The method of claim 1, wherein the recessing of the first gate spacer and the second gate spacer includes:
forming a mask within the opening over the source/drain region;
recessing the mask to a height below a height of the first and second dummy gates;
recessing the first gate spacer and the second gate spacer to the height of the mask; and
removing the mask from the opening.

9. The method of claim 8, wherein the recessing the first gate spacer and the second gate spacer includes performing an isotropic reactive ion etching of the first gate spacer and the second gate spacer such that a portion of gate spacer positioned above the height of the mask is removed.

10. (canceled)

11. (canceled)

12. (canceled)

13. (canceled)

14. (canceled)

15. A method for forming an integrated circuit structure, the method comprising:
forming a first dummy gate over a fin and forming a second dummy gate over the fin, each dummy gate having gate spacers disposed on sidewalls thereof such that an opening is disposed between a first gate spacer of the first dummy gate and a second gate spacer of the second dummy gate, the opening exposing a source/drain region within the fin;
recessing a height of the first gate spacer and the second gate spacer to a reduced height below a height of the first dummy gate and the second dummy gate;
forming an etch stop layer within the opening over the exposed source/drain region such that the etch stop layer extends vertically along the recessed first gate spacer and the recessed second gate spacer;
forming a dielectric fill over the etch stop layer within the opening to substantially fill the opening;
replacing the first dummy gate with a first replacement metal gate (RMG) structure and replacing the second dummy gate with a second RMG structure;
recessing the first RMG structure and the second RMG structure, wherein the recessing of the first RMG structure and the second RMG structure includes recessing a height of the first RMG structure and the second RMG structure to a reduced height below the reduced height of the first gate spacer and the second gate spacer;
forming a gate cap layer over each of the first RMG structure and the second RMG structure;
removing the dielectric fill to form a contact opening over the fin, the contact opening including a lower portion horizontally between the recessed first gate spacer and the recessed second gate spacer, and an upper portion horizontally between the first RMG structure and the second RMG structure; and
filling the contact opening with a contact metal, the contact metal extending continuously from an upper surface of the fin to a height substantially coplanar with the first RMG structure and the second RMG structure, such that the contact metal includes:
a lower portion on the fin horizontally between the recessed first gate spacer and the recessed second gate spacer, and having a first width, and
an upper portion horizontally between the first RMG structure and the second RMG structure, and having a second width greater than the first width, wherein the upper portion of the contact metal is positioned over the recessed first gate spacer and the recessed second gate spacer.

16. The method of claim 15, wherein the forming of the dielectric fill includes:
forming a first oxide over the etch stop layer to substantially fill the opening;
recessing the first oxide to a height above the reduced height of the first and second gate spacers;
forming a second oxide over the first oxide; and
planarizing the second oxide to the first and second RMG structure.

17. The method of claim 16, wherein the first oxide is substantially T-shaped after the recessing of the first oxide.

18. The method of claim 16, wherein the forming of the second oxide includes high-density plasma chemical vapor deposition of the second oxide.

19. The method of claim 16, wherein the recessing of the first and second RMG structure includes recessing the first and second RMG structures to a height below the height of the first oxide.

20. The method of claim 15, wherein the recessing of the first gate spacer and the second gate spacer includes:
forming a mask within the opening over the source/drain region;
recessing the mask to a height below a height of the first and second dummy gates;
performing an isotropic reactive ion etching of the first gate spacer and the second gate spacer to the height of the mask such that any portion of gate spacer disposed above the height of the mask is removed; and
removing the mask from the opening.
